(19) United States
(12) Patent Application Publication
(10) Pub. No.: US 2026/0215052 A1
(43) Pub. Date: Jul. 23, 2026

(54) Display Apparatus in which Sub-Pixels are Disposed in Each Pixel Area

(71) Applicant: LG Display Co., Ltd., Seoul (KR)

(72) Inventors: Chi Hak Lee, Paju-si (KR); Seung Kwang Roh, Paju-si (KR); Woo Chul Choi, Paju-si (KR); Sang Kyoung Moon, Paju-si (KR); Dong Il Choi, Paju-si (KR); Jung Mo Cho, Paju-si (KR); Boa Jin, Paju-si (KR); Min Gue Shin, Paju-si (KR)

(21) Appl. No.: 19/429,871

(22) Filed: Dec. 22, 2025

(30) Foreign Application Priority Data
Jan. 21, 2025 (KR) 10-2025-0008859

(51) Int. Cl. H10H 29/34; H10H 20/855

(52) U.S. Cl. CPC H10H 29/345; H10H 20/855

(57) ABSTRACT

First, second, and third sub-pixels are disposed in each pixel area of a display apparatus. Each sub-pixel includes first and second emission areas (EAs). The first EA can have a planar shape of a bar extending in a first direction. The second EA can have a planar shape different from the first EA. The second EA of each sub-pixel can be disposed side by side with the first EA of the corresponding sub-pixel in a direction perpendicular to the first direction. The first and second EAs of the first sub-pixel can be disposed in a same order as the first and second EAs of the second sub-pixel. The first and second EAs of the first sub-pixel can be disposed between the first and second EAs of the third sub-pixel. The first and second EAs of the second sub-pixel can be disposed outside the first and second EAs of the third sub-pixel.

### CROSS-REFERENCE TO RELATED APPLICATIONS

This application claims the benefit of Republic of Korea Patent Application No. 10-2025-0008859, filed on Jan. 21, 2025, which is hereby incorporated by reference as if fully set forth herein.

### BACKGROUND OF THE INVENTION

### Field of the Invention

The present disclosure relates to a display apparatus in which a plurality of sub-pixels are disposed in each pixel area.

### Discussion of the Related Art

Generally, a display apparatus provides an image to a user. For example, the display apparatus can include a plurality of light-emitting devices. Each of the light-emitting devices can emit light displaying a specific color. For example, each of the light-emitting devices can include a light-emitting unit disposed between a first electrode and a second electrode. The plurality of light-emitting devices can be disposed on a device substrate. The device substrate can include a plurality of pixel areas. Each of the pixel areas can realize various colors. For example, each of the pixel areas can include a plurality of sub-pixels. Each of the light-emitting devices can be disposed on one of the plurality of sub-pixels. Thus, in the display apparatus, the image provided to the user can include various colors. However, a leakage current may occur between different sub-pixels of each pixel area, resulting in malfunction of the corresponding sub-pixels and hence the decrease in the quality of the image.

### SUMMARY OF THE INVENTION

Accordingly, the present disclosure is directed to a display apparatus that substantially obviates one or more problems due to limitations and disadvantages of the related art.

An object of the present disclosure is to provide a display apparatus capable of minimizing the decrease in the quality of the (particularly, low-grayscale) image due to the leakage current.

Additional advantages, objects, and features of the disclosure will be set forth in part in the description which follows and in part will become apparent to those having ordinary skill in the art upon examination of the following or may be learned from practice of the disclosure. The objectives and other advantages of the disclosure may be realized and attained by the structure particularly pointed out in the written description and claims hereof as well as the appended drawings.

To achieve these objects and other advantages and in accordance with the purpose of the present disclosure, as embodied and broadly described herein, there is provided a display apparatus comprising a plurality of pixel areas. A first sub-pixel, a second sub-pixel and a third sub-pixel are disposed in each pixel area. The first sub-pixel, the second sub-pixel and the third sub-pixel in each pixel area realize different colors. Each of the first sub-pixel, the second sub-pixel and the third sub-pixel includes a first emission area and a second emission area. The first emission area has a planar shape of a bar extending in a first direction. The second emission area has a planar shape different from the first emission area. The second emission area of each of the first sub-pixel, the second sub-pixel and the third sub-pixel is disposed side by side with the first emission area of the corresponding sub-pixel in a second direction perpendicular to the first direction. The first emission area and the second emission area of the first sub-pixel is disposed in a same order as the first emission area and the second emission area of the second sub-pixel. The first emission area and the second emission area of the first sub-pixel are disposed between the first emission area and the second emission area of the third sub-pixel and the first emission area and the second emission area of the second sub-pixel are disposed outside the first emission area and the second emission area of the third sub-pixel.

The second emission area of the third sub-pixel can be disposed between the first emission area of the first sub-pixel and the second emission area of the second sub-pixel, or the first emission area of the third sub-pixel is disposed between the first emission area of the first sub-pixel and the second emission area of the second sub-pixel.

Each of the first sub-pixel, the second sub-pixel and the third sub-pixel can include a plurality of second emission areas. The plurality of second emission areas can be disposed side by side in the first direction.

At least one of the first sub-pixel, the second sub-pixel and the third sub-pixel can have a number of second emission areas different from respective numbers of second emission areas of the other sub-pixels.

A plurality of light-emitting devices can be disposed in the first emission area and the second emission area of each of the first sub-pixel, the second sub-pixel and the third sub-pixel. The plurality of light-emitting devices of the third sub-pixel can have a driving voltage higher than the plurality of light-emitting devices of the first sub-pixel and the plurality of light-emitting devices of the second sub-pixel.

The plurality of light-emitting devices can include a first light-emitting device and a second light-emitting device. The first light-emitting device can overlap the first emission area. The second light-emitting device can overlap the second emission area. The second light-emitting device can have a stacked structure same as the first light-emitting device.

The first emission area and the second emission area of the third sub-pixel can emit green light.

A distance between the first emission area of the first sub-pixel and the first emission area of the second sub-pixel of each pixel area can be smaller than a distance between the first emission area of the second sub-pixel of each pixel area and the first emission area of the first sub-pixel of the pixel area adjacent to the corresponding pixel area in the second direction. A distance between the second emission area of the first sub-pixel and the second emission area of the second sub-pixel of each pixel area can be smaller than a distance between the second emission area of the second sub-pixel of each pixel area and the second emission area of the first sub-pixel of the pixel area adjacent to the corresponding pixel area in the second direction.

The distance between the first emission area of the first sub-pixel and the first emission area of the second sub-pixel of each pixel area may be the same as the distance between the second emission area of the first sub-pixel and the second emission area of the second sub-pixel of the corresponding pixel area in the second direction.

The first emission areas of the first sub-pixel, the second sub-pixel and the third sub-pixel can have different lengths in the first direction.

The first emission area of the third sub-pixel can have a smaller length than the first emission area of the first sub-pixel in the first direction, and the first emission area of the second sub-pixel can have a smaller length than the first emission area of the third sub-pixel in the first direction.

The second emission areas of the first sub-pixel, the second sub-pixel and the third sub-pixel can have the same length in the second direction.

Light emitted from the first emission area of each sub-pixel can have a viewing angle wider than light emitted from the second emission area of each sub-pixel, or the first emission area of each sub-pixel may be configured to realize a first image and the second emission area of each sub-pixel may be configured to realize a second image different from the first image.

A first pixel lens can be disposed to overlap the first emission area of each sub-pixel and a second pixel lens can be disposed to overlap the second emission area of each sub-pixel.

A lens passivation layer can be disposed on the first pixel lens and the second pixel lens.

A refractive index of the lens passivation layer can be smaller than a refractive index of the first pixel lens and a refractive index of the second pixel lens.

A barrier structure can be disposed outside the first emission area and the second emission area defined in each sub-pixel.

The barrier structure can have a stacked structure of a first barrier pattern and a second barrier pattern disposed on the first barrier pattern.

The second barrier pattern can be spaced apart from the first barrier pattern by an optical insulating layer covering the first barrier pattern.

A pixel lens can be disposed in the second emission area of each sub-pixel, and a lens passivation layer can be disposed on the pixel lens and can be in direct contact with the optical insulating layer in the first emission area.

The first sub-pixel may be one of a blue sub-pixel, a red sub-pixel and a green sub-pixel, the second sub-pixel may be another of the blue sub-pixel, the red sub-pixel, and the green sub-pixel, and the third sub-pixel may be the remaining one of the blue sub-pixel, the red sub-pixel and the green sub-pixel.

### BRIEF DESCRIPTION OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a partial sectional perspective view schematically showing a display apparatus according to an embodiment of the present disclosure;

FIG. 2 is an enlarged view of region K1 in FIG. 1;

FIG. 3 is an enlarged view of region K2 in FIG. 2;

FIG. 4 is a view showing a driving circuit of a sub-pixel in the display apparatus according to the embodiment of the present disclosure;

FIG. 5 is a view taken along line I-I′ of FIG. 2;

FIG. 6 is a view taken along line II-II′ of FIG. 3;

FIGS. 7 to 9 are enlarged views of alternative examples of region K2 in FIG. 2; and

FIG. 10 is a partial top view showing a display apparatus according to another embodiment of the present disclosure.

### DETAILED DESCRIPTION OF THE INVENTION

Hereinafter, details related to the above objects, technical configurations, and operational effects of the embodiments of the present disclosure will be clearly understood by the following detailed description with reference to the drawings, which illustrate some embodiments of the present disclosure. Here, the embodiments of the present disclosure are provided in order to allow the technical sprit of the present disclosure to be satisfactorily transferred to those skilled in the art, and thus the present disclosure may be embodied in other forms and is not limited to the embodiments described below.

In addition, the same or extremely similar elements may be designated by the same reference numerals throughout the specification and in the drawings, the lengths and thickness of layers and regions may be exaggerated for convenience. It will be understood that, when a first element is referred to as being “on” a second element, although the first element may be disposed on the second element so as to come into contact with the second element, a third element may be interposed between the first element and the second element.

Here, terms such as, for example, “first” and “second” may be used to distinguish any one element with another element. However, the first element and the second element may be arbitrary named according to the convenience of those skilled in the art without departing the technical sprit of the present disclosure.

The terms used in the specification of the present disclosure are merely used in order to describe particular embodiments, and are not intended to limit the scope of the present disclosure. For example, an element described in the singular form is intended to include a plurality of elements unless the context clearly indicates otherwise. In addition, in the specification of the present disclosure, it will be further understood that the terms “comprises” and “includes” specify the presence of stated features, integers, steps, operations, elements, components, and/or combinations thereof, but do not preclude the presence or addition of one or more other features, integers, steps, operations, elements, components, and/or combinations.

And, unless ‘directly’ is used, the terms “connected” and “coupled” may include that two components are “connected” or “coupled” through one or more other components located between the two components.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

### Embodiment

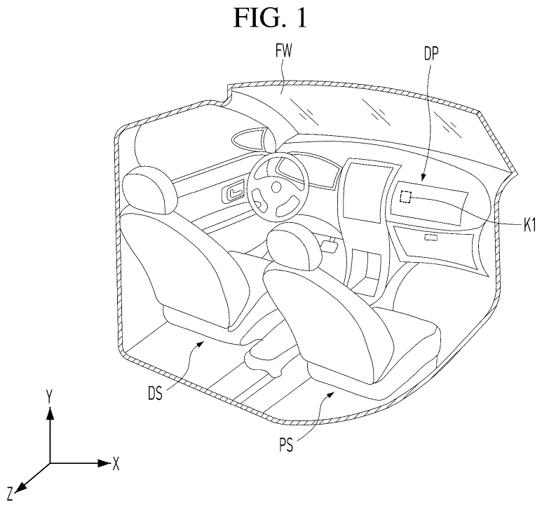

FIG. 1 is a partial sectional perspective view schematically showing a display apparatus according to an embodiment of the present disclosure.

Referring to FIG. 1, the display apparatus according to the embodiment of the present disclosure can include a display panel DP disposed inside a car. The display panel DP can generate an image. The image realized by the display panel DP can be provided to a driver sitting in a driver seat DS or a passenger sitting in a passenger seat PS. For example, the display panel DP can provide one of a first image containing information necessary for the driving of the car and a second image containing information unrelated to the driving of the car. The first image can be shared with the driver sitting in the driver seat DS and the passenger sitting in the passenger seat PS. The second image can't be recognized by the driver sitting in the driver seat DS. For example, the second image can be provided while the car is in the driving. The display panel DP can be disposed in front of the passenger seat PS. Thus, in the display apparatus according to the embodiment of the present disclosure, gaze dispersion of the driver sitting in the driver seat DS due to the second image can be prevented. Therefore, in the display apparatus according to the embodiment of the present disclosure, the accidents due to gaze dispersion of the driver can be minimized.

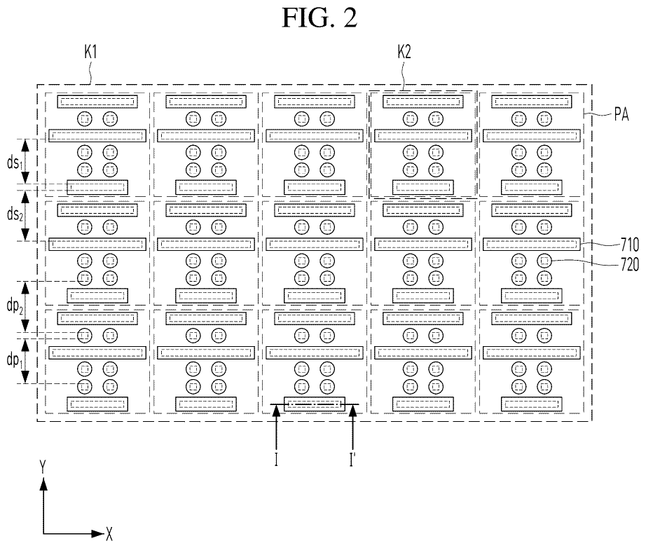

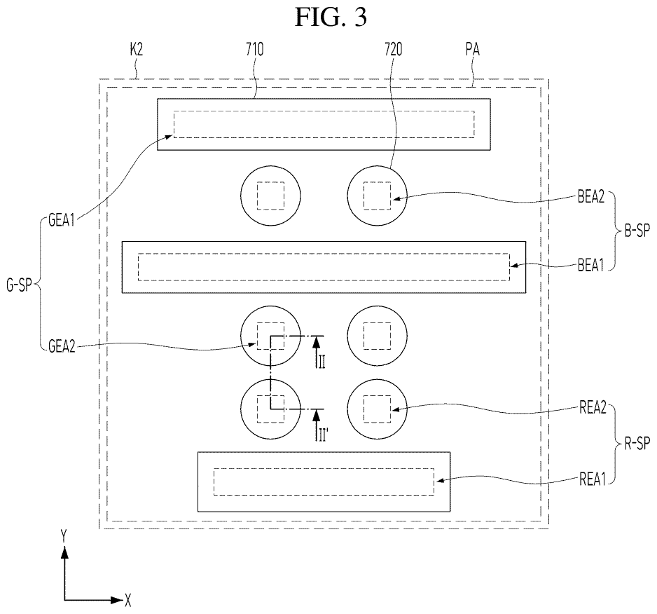

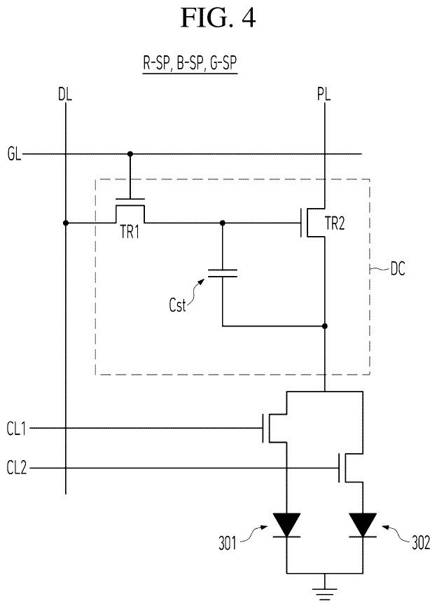

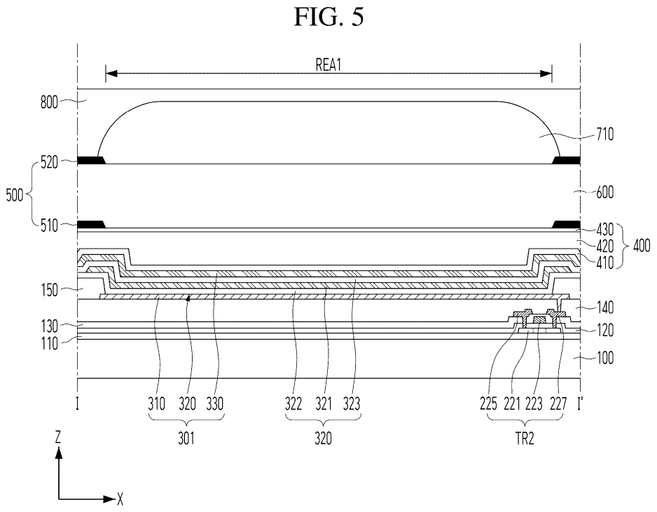

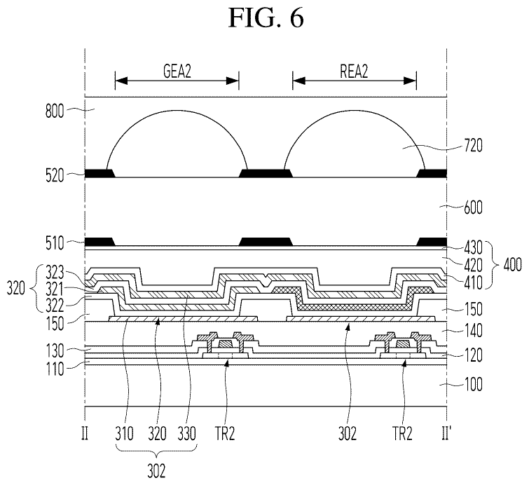

FIG. 2 is an enlarged view of region K1 in FIG. 1. FIG. 3 is an enlarged view of region K2 in FIG. 2. FIG. 4 is a view showing a driving circuit of a sub-pixel in the display apparatus according to the embodiment of the present disclosure. FIG. 5 is a view taken along line I-I′ of FIG. 2. FIG. 6 is a view taken along line II-II′ of FIG. 3.

Referring to FIGS. 1 to 6, the display apparatus according to the embodiment of the present disclosure can include a plurality of pixel areas PA disposed in the display panel DP. The plurality of pixel areas PA can be arranged in a matrix form. For example, the plurality of pixel areas PA can be disposed side by side in a first direction X and a second direction Y perpendicular to the first direction X. Herein, the first direction X is a direction from the driver seat DS toward the passenger seat PS or vice versa. A front wind-shield FW of the car can be disposed side by side with the display panel DP in the second direction Y. For example, a third direction Z perpendicular to the first direction X and the second direction Y can be a direction toward the passenger seat PS from the display panel DP.

Each of the pixel areas PA can realize various colors. For example, a plurality of sub-pixels (R-SP, B-SP and G-SP, see FIG. 3) can be disposed in each pixel area PA. Each of the plurality of sub-pixels (R-SP, B-SP and G-SP) can realize a specific color according to a signal applied through a plurality of signal wirings (GL, DL, PL, CL1 and CL2, see FIG. 6). For example, a red sub-pixel R-SP realizing a red color, a blue sub-pixel B-SP realizing a blue color, and a green sub-pixel G-SP realizing a green color can be disposed in each pixel area PA.

A driving circuit DC electrically connected to the plurality of signal wirings (GL, DL, PL, CL1 and CL2, see FIG. 4) and a plurality of light-emitting devices (301 and 302, see FIG. 4) electrically connected to the driving circuit DC can be disposed in each sub-pixel (R-SP, B-SP and G-SP). The plurality of signal wirings (GL, DL, PL, CL1 and CL2) can include a gate line GL applying a gate signal, a data line DL applying a data signal, and a power voltage supply line PL supplying a power voltage. For example, the driving circuit DC of each sub-pixel (R-SP, B-SP and G-SP) can supply a driving current corresponding to the data signal to at least one of the plurality of light-emitting devices (301 and 302) of the corresponding sub-pixel (R-SP, B-SP and G-SP) according to the gate signal using the power voltage for one frame. For example, the driving circuit DC of each sub-pixel (R-SP, B-SP and G-SP) can include a first thin film transistor TR1, a second thin film transistor TR2 and a storage capacitor Cst.

The first thin film transistor TR1 can transmit the data signal to the second thin film transistor TR2 according to the gate signal. For example, the first thin film transistor TR1 can function as a switching thin film transistor. The first thin film transistor TR1 can include a first semiconductor pattern, a first gate electrode, a first drain electrode and a first source electrode. For example, the first gate electrode can be electrically connected to the gate line GL, and the first drain electrode can be electrically connected to the date line DL.

The second thin film transistor TR2 can generate the driving current using the power voltage. For example, the second thin film transistor TR2 can function as a driving thin film transistor. The second thin film transistor TR2 can include a second semiconductor pattern 221, a second gate electrode 223, a second drain electrode 225 and a second source electrode 227 (see FIG. 5). For example, the second gate electrode 223 can be electrically connected to the first source electrode, and the second drain electrode 225 can be electrically connected to the power voltage supply line PL.

The second semiconductor pattern 221 can include a semiconductor material. For example, the second semiconductor pattern 221 can include an oxide semiconductor, such as IGZO. The second semiconductor pattern 221 can include a drain region, a source region and a channel region disposed between the drain region and the source region. The drain region and the source region can have a resistance smaller than the channel region. For example, the drain region and the source region can include a conductive region of an oxide semiconductor. The channel region can be a region of an oxide semiconductor which is not conductorized.

The second semiconductor pattern 221 can include a same material as the first semiconductor pattern. The second semiconductor pattern 221 can be disposed on a same layer as the first semiconductor pattern. The second semiconductor pattern 221 can be formed by a same process as the first semiconductor pattern. For example, the second semiconductor pattern 221 can be formed simultaneously with the first semiconductor pattern.

The second gate electrode 223 can be disposed on a portion of the second semiconductor pattern 221. For example, the second gate electrode 223 can overlap the channel region of the second semiconductor pattern 221. The drain region and the source region of the second semiconductor pattern 221 can be disposed outside the second gate electrode 223. The second gate electrode 223 can include a conductive material. For example, the second gate electrode 223 can include a metal, such as aluminum (Al), chrome (Cr), copper (Cu), molybdenum (Mo), titanium (Ti) and tungsten (W). The second gate electrode 223 can be spaced apart from the second semiconductor pattern 221. The second gate electrode 223 can be insulated from the second semiconductor pattern 221. For example, the channel region of the second semiconductor pattern 221 can have an electrical conductivity corresponding to a voltage of a signal applied to the second gate electrode 223.

The second gate electrode 223 can include a same material as the first gate electrode. The second gate electrode 223 can be disposed on a same layer as the first gate electrode. The second gate electrode 223 can be formed by a same process as the first gate electrode. For example, the second gate electrode 223 can be formed simultaneously with the first gate electrode.

The second drain electrode 225 can be electrically connected to the drain region of the second semiconductor pattern 221. The second drain electrode 225 can include a conductive material. For example, the second drain electrode 225 can include a metal, such as aluminum (Al), chrome (Cr), copper (Cu), molybdenum (Mo), titanium (Ti) and tungsten (W). The second drain electrode 225 can be insulated from the second gate electrode 223. The second drain electrode 225 can include a different material from the second gate electrode 223. For example, the second drain electrode 225 can be disposed on a different layer from the second gate electrode 223.

The second drain electrode 225 can include a same material as the first drain electrode. The second drain electrode 225 can be disposed on a same layer as the first drain electrode. The second drain electrode 225 can be formed by a same process as the first drain electrode. For example, the second drain electrode 225 can be formed simultaneously with the first drain electrode.

The second source electrode 227 can be electrically connected to the source region of the second semiconductor pattern 221. The second source electrode 227 can include a conductive material. For example, the second source electrode 227 can include a metal, such as aluminum (Al), chrome (Cr), copper (Cu), molybdenum (Mo), titanium (Ti) and tungsten (W). The second source electrode 227 can be insulated from the second gate electrode 223. The second source electrode 227 can include a different material from the second gate electrode 223. For example, the second source electrode 227 can be disposed on a different layer from the second gate electrode 223.

The second source electrode 227 can be disposed on a same layer as the second drain electrode 225. The second source electrode 227 can include a same material as the second drain electrode 225. The second source electrode 227 can be formed by a same process as the second drain electrode 225. For example, the second source electrode 227 can be formed simultaneously with the second drain electrode 225. The second source electrode 227 can be spaced apart from the second drain electrode 225.

The second source electrode 227 can include a same material as the first source electrode. The second source electrode 227 can be disposed on a same layer as the first source electrode. The second source electrode 227 can be formed by a same process as the first source electrode. For example, the second source electrode 227 can be formed simultaneously with the first source electrode.

The storage capacitor Cst can maintain a voltage of the signal applied to the second gate electrode 223 for one frame. The storage capacitor Cst can have a stacked structure of capacitor electrodes. For example, the storage capacitor Cst can have a structure in which a first capacitor electrode electrically connected to the second gate electrode 233 and a second capacitor electrode electrically connected to the second source electrode 227 are stacked. The storage capacitor Cst can be formed using a process of forming the first thin film transistor TR1 and the second thin film transistor TR2. For example, the first capacitor electrode can be disposed on a same layer as the second gate electrode 223, and the second capacitor electrode can be disposed on a same layer as the second source electrode 227.

The driving circuit DC of each sub-pixel (R-SP, B-SP and G-SP) can be supported by a device substrate 100. The device substrate 100 can include an insulating material. For example, the device substrate 100 can include glass or plastic. At least one of a plurality of insulating layers (110, 120, 130, 140 and 150, see FIG. 5) for preventing unintended electrical connection can be disposed on the device substrate 100. For example, a buffer insulating layer 110, a gate insulating layer 120, an interlayer insulating layer 130, a planarization layer 140 and a bank insulating layer 150 can be disposed on the device substrate 100.

The buffer insulating layer 110 can be disposed on the device substrate 100. The buffer insulating layer 110 can prevent pollution due to the device substrate 100 in a process of forming the driving circuit DC of each sub-pixel (R-SP, B-SP and G-SP). For example, an upper surface of the device substrate 100 toward the driving circuit DC of each sub-pixel (R-SP, B-SP and G-SP) can be covered by the buffer insulating layer 110. The first thin film transistor TR1, the second thin film transistor TR2 and the storage capacitor Cst of each sub-pixel (R-SP, B-SP and G-SP) can be disposed on the buffer insulating layer 110. The buffer insulating layer 110 can include an insulating material. For example, the buffer insulating layer 110 can be an inorganic insulating layer made of an inorganic insulating material, such as silicon oxide (SiOx) and silicon nitride (SiNx).

The gate insulating layer 120 can be disposed on the buffer insulating layer 110. The second gate electrode 223 of each sub-pixel (R-SP, B-SP and G-SP) can be insulated from the second semiconductor pattern 221 of the corresponding sub-pixel (R-SP, B-SP and G-SP) by the gate insulating layer 120. For example, the gate insulating layer 120 can cover the first semiconductor pattern and the second semiconductor pattern 221 of each sub-pixel (R-SP, B-SP and G-SP). The first gate electrode and the second gate electrode 223 of each sub-pixel (R-SP, B-SP and G-SP) can be disposed on the gate insulating layer 120. The gate insulating layer 120 can include an insulating material. For example, the gate insulating layer 120 can be an inorganic insulating layer made of an inorganic insulating material, such as silicon oxide (SiOx) and silicon nitride (SiNx).

The interlayer insulating layer 130 can be disposed on the gate insulating layer 120. The second drain electrode 225 and the second source electrode 227 of each sub-pixel (R-SP, B-SP and G-SP) can be insulated from the second gate electrode 223 of the corresponding sub-pixel (R-SP, B-SP and G-SP) by the interlayer insulating layer 130. For example, the interlayer insulating layer 130 can cover the first gate electrode and the second gate electrode 223 of each sub-pixel (R-SP, B-SP and G-SP). The first drain electrode, the first source electrode, the second drain electrode 225 and the second source electrode 227 of each sub-pixel (R-SP, B-SP and G-SP) can be disposed on the interlayer insulating layer 130. The interlayer insulating layer 130 can include an insulating material. For example, the interlayer insulating layer 130 can be an inorganic insulating layer made of an inorganic insulating material.

The planarization layer 140 can be disposed on the interlayer insulating layer 130. For example, the first drain electrode, the first source electrode, the second drain electrode 225 and the second source electrode 227 of each sub-pixel (R-SP, B-SP and G-SP) can be covered by the planarization layer 140. The planarization layer 140 can include an insulating material. The planarization layer 140 can include a material having a relative high fluidity. For example, the planarization layer 140 can be an organic insulating layer made of an organic insulating material. A thickness difference due to the driving circuit DC of each sub-pixel (R-SP, B-SP and G-SP) can be removed by the planarization layer 140. For example, an upper surface of the planarization layer 140 opposite to the device substrate 100 can be flat.

The bank insulating layer 150 can be disposed on the planarization layer 140. The bank insulating layer 150 can include an insulating material. For example, the bank insulating layer 150 can be an organic insulating layer made of an organic insulating material. The bank insulating layer 150 can define a first emission area (REA1, BEA1 and GEA1, see FIG. 3) and a second emission area (REA2, BEA2 and GEA2) in each sub-pixel (R-SP, B-SP and G-SP). For example, the upper surface of the planarization layer 140 overlapping with the first emission area (REA1, BEA1 and GEA1) and the second emission area (REA2, BEA2 and GEA2) in each sub-pixel (R-SP, B-SP and G-SP) can be exposed by the bank insulating layer 150.

The first emission area (REA1, BEA1 and GEA1) of each sub-pixel (R-SP, B-SP and G-SP) can have a planar shape of a bar extending in the first direction X. The first emission area (REA1, BEA1 and GEA1) of each sub-pixel (R-SP, B-SP and G-SP) can have a different length from the first emission area (REA1, BEA1 and GEA1) of adjacent sub-pixel (R-SP, B-SP and G-SP) in each pixel area PA. For example, the first green emission area GEA1 of the green sub-pixel G-SP can have a smaller length than the first blue emission area BEA1 of the blue sub-pixel B-SP in the first direction X, and the first red emission area REA1 of the red sub-pixel R-SP can have a smaller length than the first green emission area GEA1 of the green sub-pixel G-SP in the first direction X.

The second emission area (REA2, BEA2 and GEA2) of each sub-pixel (R-SP, B-SP and G-SP) can have a planar shape different from the first emission area (REA1, BEA1 and GEA1) of the corresponding sub-pixel (R-SP, B-SP and G-SP). The planar shape of the second emission area (REA2, BEA2 and GEA2) of each sub-pixel (R-SP, B-SP and G-SP) can have a same shape as the planar shape of the second emission area (REA2, BEA2 and GEA2) of adjacent sub-pixel (R-SP, B-SP and G-SP) in each pixel area PA. For example, the second emission area (REA2, BEA2 and GEA2) of each sub-pixel (R-SP, B-SP and G-SP) can have a plane of circular shape. The second emission area (REA2, BEA2 and GEA2) of each sub-pixel (R-SP, B-SP and G-SP) can have a small length than the first emission area (REA1, BEA1 and GEA1) of the corresponding sub-pixel (R-SP, B-SP and G-SP) in the first direction X. Thus, in the display apparatus according to the embodiment of the present disclosure, light emitted from the first emission area (REA1, BEA1 and GEA1) of each sub-pixel (R-SP, B-SP and G-SP) can have a viewing angle wider than light emitted from the second emission area (REA2, BEA2 and GEA2) of each sub-pixel (R-SP, B-SP and G-SP) in the first direction X. The second emission area (REA2, BEA2 and GEA2) of each sub-pixel (R-SP, B-SP and G-SP) can have a same length as the first emission area (REA1, BEA1 and GEA1) of the corresponding sub-pixel (R-SP, B-SP and G-SP) in the second direction Y. For example, the light emitted from the first emission area (REA1, BEA1 and GEA1) of each sub-pixel (R-SP, B-SP and G-SP) can have a viewing angle same as the light emitted from the second emission area (REA2, BEA2 and GEA2) of each sub-pixel (R-SP, B-SP and G-SP) in the second direction Y.

The second emission area (REA2, BEA2 and GEA2) of each sub-pixel (R-SP, B-SP and G-SP) can be disposed side by side with the first emission area (REA1, BEA1 and GEA1) of the corresponding sub-pixel (R-SP, B-SP and G-SP) in the second direction Y. The number of the second emission area (REA2, BEA2 and GEA2) defined in each sub-pixel (R-SP, B-SP and G-SP) can be different from the number of the first emission area (REA1, BEA1 and GEA1) defined in the corresponding sub-pixel (R-SP, B-SP and G-SP). For example, a single first emission area (REA1, BEA1 and GEA1) and two second emission areas (REA2, BEA2 and GEA2) can be defined in each sub-pixel (R-SP, B-SP and G-SP). The two second emission areas (REA2, BEA2 and GEA2) defined in each sub-pixel (R-SP, B-SP and G-SP) can be disposed side by side in the first direction X.

The plurality of light-emitting devices (301 and 302) of each sub-pixel (R-SP, B-SP and G-SP) can overlap the first emission area (REA1, BEA1 and GEA1) and the second emission area (REA2, BEA2 and GEA2) defined in the corresponding sub-pixel (R-SP, B-SP and G-SP). For example, the plurality of light-emitting devices (301 and 302) of each sub-pixel (R-SP, B-SP and G-SP) can include a first light-emitting device 301 overlapping with the first emission area (REA1, BEA1 and GEA1) of the corresponding sub-pixel (R-SP, B-SP and G-SP) and a second light-emitting device 302 overlapping with the second emission area (REA2, BEA2 and GEA2) of the corresponding sub-pixel (R-SP, B-SP and G-SP).

The first light-emitting device 301 of each sub-pixel (R-SP, B-SP and G-SP) can be disposed on the planarization layer 140. The first light-emitting device 301 of each sub-pixel (R-SP, B-SP and G-SP) can emit light displaying a color realized by the corresponding sub-pixel (R-SP, B-SP and G-SP). For example, the first light-emitting device 301 of the red sub-pixel R-SP can emit red light, the first light-emitting device 301 of the blue sub-pixel B-SP can emit blue light, and the first light-emitting device 301 of the green sub-pixel G-SP can emit green light. The first light-emitting device 301 of each sub-pixel (R-SP, B-SP and G-SP) can include a first electrode 310, a light-emitting unit 320 and a second electrode 330, which are sequentially stacked on the upper surface of the planarization layer 140.

The first electrode 310 and the second electrode 330 can include a conductive material. The second electrode 330 can include a different material from the first electrode 310. For example, a transmittance of the second electrode 330 can be higher than a transmittance of the first electrode 310. The first electrode 310 can have a higher reflectance than the second electrode 330. For example, the first electrode 310 can be a reflective electrode including a metal, such as aluminum (Al) and silver (Ag), and the second electrode 330 can be a transparent electrode made of a transparent conductive material, such as ITO and IZO.

The light-emitting unit 320 can generate light having luminance corresponding to a voltage difference between the first electrode 310 and the second electrode 330. For example, the light-emitting unit 320 can include an emission material layer (EML) 321. The emission material layer 321 can include an organic emission material, an inorganic emission material, or a hybrid emission material. The light-emitting unit 320 can have a multi-layer structure. For example, the light-emitting unit 320 can include a first functional layer 322 disposed between the first electrode 310 and the emission material layer 321 and a second functional layer 323 disposed between the emission material layer 321 and the second electrode 330. Holes and electrons can be smoothly supplied to the emission material layer 321 by the first function layer 322 and the second function layer 323. For example, each of the first function layer 322 and the second function layer 323 can include at least one of a hole injection layer (HIL), a hole transport layer (HTL), an electron transport layer (ETL) and an electron injection layer (EIL). The light generated by the light-emitting unit 320 can be emitted through the second electrode 330.

The second light-emitting device 302 of each sub-pixel (R-SP, B-SP and G-SP) can be disposed on the planarization layer 140. The light emitted from the second light-emitting device 302 of each sub-pixel (R-SP, B-SP and G-SP) can display a same color as the light emitted from the first light-emitting device 301 of the corresponding sub-pixel (R-SP, B-SP and G-SP). For example, the second light-emitting device 302 of the red sub-pixel R-SP can emit red light, the second light-emitting device 302 of the blue sub-pixel B-SP can emit blue light, and the second light-emitting device 302 of the green sub-pixel G-SP can emit green light. The second light-emitting device 302 of each sub-pixel (R-SP, B-SP and G-SP) can have a stacked structure same as the first light-emitting device 301 of the corresponding sub-pixel (R-SP, B-SP and G-SP). For example, the second light-emitting device 302 of each sub-pixel (R-SP, B-SP and G-SP) can include the first electrode 310, the light-emitting unit 320 and the second electrode 330, which are sequentially stacked on the upper surface of the planarization layer 140.

The first electrode 310 of the second light-emitting device 302 of each sub-pixel (R-SP, B-SP and G-SP) can be insulated from the first electrode 310 of the first light-emitting device 301 of the corresponding sub-pixel (R-SP, B-SP and G-SP) by the bank insulating layer 150. For example, an edge of each of the first electrodes 310 on each sub-pixel area (R-SP, B-SP and G-SP) can be covered by the bank insulating layer 150. The emission material layer 321 of the second light-emitting device 302 of each sub-pixel (R-SP, B-SP and G-SP) can be spaced apart from the emission material layer 321 of the first light-emitting device 301 of the corresponding sub-pixel (R-SP, B-SP and G-SP). For example, the first light-emitting device 301 and the second light-emitting device 302 of each sub-pixel (R-SP, B-SP and G-SP) can include the emission material layer 321 surrounded by the first functional layer 322 and the second functional layer 323. The first functional layer 322 and the second functional layer 323 of each sub-pixel (R-SP, B-SP and G-SP) can extend along a surface of the bank insulating layer 150 opposite to the device substrate 100. For example, each of the first functional layer 322 and the second functional layer 323 of each sub-pixel (R-SP, B-SP and G-SP) can include a region overlapping with the first emission area (REA1, BEA1 and GEA1) of the corresponding sub-pixel (R-SP, B-SP and G-SP) and a region overlapping with the second emission area (REA2, BEA2 and GEA2) of the corresponding sub-pixel (R-SP, B-SP and G-SP). Thus, the first functional layer 322 and the second functional layer 323 may be common layers shared by the plurality of sub-pixels in each pixel area PA, and a leakage current may occur between adjacent sub-pixels (particularly, between the red sub-pixel R-SP and the blue sub-pixel B-SP) through the common layers.

The color of each sub-pixel (R-SP, B-SP and G-SP) can be realized by the first light-emitting device 301 of the corresponding sub-pixel (R-SP, B-SP and G-SP) or the second light-emitting device 302 of the corresponding sub-pixel (R-SP, B-SP and G-SP). For example, the driving current generated by the driving circuit DC of each sub-pixel (R-SP, B-SP and G-SP) can be supplied to the first electrode 310 of the first light-emitting device 301 of the corresponding sub-pixel (R-SP, B-SP and G-SP), or the first electrode 310 of the second light-emitting device 302 of the corresponding sub-pixel (R-SP, B-SP and G-SP). At least one switching thin film transistor for selectively connecting the driving circuit DC to the first light-emitting device 301 or the second light-emitting device 302 can be disposed in each sub-pixel (R-SP, B-SP and G-SP). For example, in the display apparatus according to the embodiment of the present disclosure, a first control thin film transistor TC1 can be disposed between the second source electrode 227 of each sub-pixel (R-SP, B-SP and G-SP) and the first light-emitting device 301 of the corresponding sub-pixel (R-SP, B-SP and G-SP), and a second control thin film transistor TC2 can be disposed between the second source electrode 227 of each sub-pixel (R-SP, B-SP and G-SP) and the second light-emitting device 302 of the corresponding sub-pixel (R-SP, B-SP and G-SP), as shown in FIG. 4. The plurality of signal wirings (GL, DL, PL, CL1 and CL2) can include a first control line CL1 applying a first control signal for turning on/off the first control thin film transistor TC1 of each sub-pixel (R-SP, B-SP and G-SP), and a second control line CL2 applying a second control signal for turning on/off the second control thin film transistor TC2 of each sub-pixel (R-SP, B-SP and G-SP). Thus, in the display apparatus according to the embodiment of the present disclosure, an image by the first light-emitting device 301 of each sub-pixel (R-SP, B-SP and G-SP) or the second light-emitting device 302 of each sub-pixel (R-SP, B-SP and G-SP) can be selectively realized. For example, the display panel DP can be disposed in front of the passenger seat PS. When the first image containing information necessary for the driving of the car is realized by the first light-emitting device 301 of each sub-pixel, the first image can be shared with the driver sitting in the driver seat DS and the passenger sitting in the passenger seat PS because light emitted from the first light-emitting device 301 of each sub-pixel can have a viewing angle wider than light emitted from the second light-emitting device 302 of each sub-pixel. When the second image containing information unrelated to the driving of the car is realized by the second light-emitting device 302 of each sub-pixel, the second image can't be recognized by the driver sitting in the driver seat DS for a narrow viewing angle of light emitted from the second light-emitting device 302 of each sub-pixel. Thus, in the display apparatus according to the embodiment of the present disclosure, gaze dispersion of the driver sitting in the driver seat DS due to the second image can be prevented, and the accidents due to gaze dispersion of the driver can be minimized.

As shown in FIGS. 2 and 3, the blue sub-pixel B-SP of each pixel area PA can be disposed side by side with the red sub-pixel R-SP of the corresponding pixel area PA in the second direction Y. The first blue emission area BEA1 and the second blue emission area BEA2 of the blue sub-pixel B-SP in each pixel area PA can be disposed in a same order as the first red emission area REA1 and the second red emission area REA2 of the red sub-pixel R-SP in the corresponding pixel area PA. For example, the first blue emission area BEA1 of the blue sub-pixel B-SP in each pixel area PA can be disposed between the second blue emission area BEA2 of the blue sub-pixel B-SP and the second red emission area REA2 of the red sub-pixel R-SP in the corresponding pixel area PA in the second direction Y.

The first blue emission area BEA1 and the second blue emission area BEA2 of the blue sub-pixel B-SP in each pixel area PA can be disposed between the first green emission area GEA1 and the second green emission area GEA2 of the green sub-pixel G-SP in the corresponding pixel area PA. The first red emission area REA1 and the second red emission area REA2 of the red sub-pixel R-SP in each pixel area PA can be disposed outside the green sub-pixel G-SP. For example, the second green emission area GEA2 of the green sub-pixel G-SP in each pixel area PA can be disposed between the first blue emission area BEA1 of the blue sub-pixel B-SP and the second red emission area REA2 of the red sub-pixel R-SP in the corresponding pixel area PA in the second direction Y. Thus, in the display apparatus according to the embodiment of the present disclosure, a distance ds1 between the first blue emission area BEA1 of the blue sub-pixel B-SP and the first red emission area REA1 of the red sub-pixel R-SP in the second direction Y in each pixel area PA and a distance dp1 between the second blue emission area BEA2 of the blue sub-pixel B-SP and the second red emission area REA2 of the red sub-pixel R-SP in the second direction Y in each pixel area PA can be increased by the second green emission area GEA2 of the green sub-pixel G-SP in the corresponding pixel area PA. For example, in the display apparatus according to the embodiment of the present disclosure, the distance dp1 between the second blue emission area BEA2 of the blue sub-pixel B-SP and the second red emission area REA2 of the red sub-pixel R-SP in the second direction Y in each pixel area PA can be a same as the distance ds1 between the first blue emission area BEA1 of the blue sub-pixel B-SP and the first red emission area REA1 of the red sub-pixel R-SP in the second direction Y in the corresponding pixel area PA.

A leakage current between the red sub-pixel R-SP and the blue sub-pixel B-SP of each pixel area PA can be blocked by the second green emission area GEA2 of the green sub-pixel G-SP in the corresponding pixel area PA. Thus, in the display apparatus according to the embodiment of the present disclosure, the current leaked from the first red emission area REA1 of the red sub-pixel R-SP in each pixel area PA can't be transmitted to the first blue emission area BEA1 of the blue sub-pixel B-SP in the corresponding pixel area PA, and the current leaked from the first blue emission area BEA1 of the blue sub-pixel B-SP in each pixel area PA can't be transmitted to the first red emission area REA1 of the red sub-pixel R-SP in the corresponding pixel area PA. And, in the display apparatus according to the embodiment of the present disclosure, the current leaked from the second red emission area REA2 of the red sub-pixel R-SP in each pixel area PA can't be transmitted to the second blue emission area BEA2 of the blue sub-pixel B-SP in the corresponding pixel area PA, and the current leaked from the second blue emission area BEA2 of the blue sub-pixel B-SP in each pixel area PA can't be transmitted to the second red emission area REA2 of the red sub-pixel R-SP in the corresponding pixel area PA. Therefore, in the display apparatus according to the embodiment of the present disclosure, the malfunction of the red sub-pixel R-SP and the blue sub-pixel B-SP of each pixel area PA due to the leakage current can be prevented.

The second light-emitting device 302 of the green sub-pixel G-SP in each pixel area PA can have a driving voltage higher than the second light-emitting device 302 of the blue sub-pixel B-SP in the corresponding pixel area PA. For example, in the display apparatus according to the embodiment of the present disclosure, the second light-emitting device 302 of the green sub-pixel G-SP in each pixel area PA can't be operated by the current leaked from the second red emission area REA2 of the red sub-pixel R-SP in the corresponding pixel area PA. The second light-emitting device 302 of the green sub-pixel G-SP in each pixel area PA can have a driving voltage higher than the second light-emitting device 302 of the red sub-pixel R-SP in the corresponding pixel area PA. For example, in the display apparatus according to the embodiment of the present disclosure, the second light-emitting device 302 of the green sub-pixel G-SP in each pixel area PA can't be operated by the current leaked from the second blue emission area BEA2 of the blue sub-pixel B-SP in the corresponding pixel area PA. Therefore, in the display apparatus according to the embodiment of the present disclosure, the malfunction of the second green emission area GEA2 of the green sub-pixel G-SP in each pixel area PA due to the leakage current can be prevented.

A distance ds2 between the first red emission area REA1 of the red sub-pixel R-SP in each pixel area PA and the first blue emission area BEA1 of the blue sub-pixel B-SP in the pixel area PA adjacent to the corresponding pixel area PA in the second direction Y can be larger than the distance ds1 between the first blue emission area BEA1 of the blue sub-pixel B-SP and the first red emission area REA1 of the red sub-pixel R-SP in the second direction Y in the corresponding pixel area PA. For example, in the display apparatus according to the embodiment of the present disclosure, the first red emission area REA1 of the red sub-pixel R-SP and the first blue emission area BEA1 of the blue sub-pixel B-SP in each pixel area PA can't be operated by the current leaked from the blue sub-pixel B-SP or the red sub-pixel R-SP of the pixel area PA adjacent to the corresponding pixel area PA in the second direction Y. A distance dp2 between the second red emission area REA2 of the red sub-pixel R-SP in each pixel area PA and the second blue emission area BEA2 of the blue sub-pixel B-SP in the pixel area PA adjacent to the corresponding pixel area PA in the second direction Y can be larger than the distance dp1 between the second blue emission area BEA2 of the blue sub-pixel B-SP and the second red emission area REA2 of the red sub-pixel R-SP in the second direction Y in the corresponding pixel area PA. For example, in the display apparatus according to the embodiment of the present disclosure, the second red emission area REA2 of the red sub-pixel R-SP and the second blue emission area BEA2 of the blue sub-pixel B-SP in each pixel area PA can't be operated by the current leaked from the blue sub-pixel B-SP or the red sub-pixel R-SP of the pixel area PA adjacent to the corresponding pixel area PA in the second direction Y. Thus, in the display apparatus according to the embodiment of the present disclosure, the malfunction of the red sub-pixel R-SP and the blue sub-pixel B-SP in each pixel area PA due to the current leaked from adjacent pixel area PA can be effectively prevented.

It should be noted that the position of the red sub-pixel and the position of the blue sub-pixel can be exchangeable. That is, the first red emission area REA1 and the second red emission area REA2 of the red sub-pixel R-SP in each pixel area PA can be disposed between the first green emission area GEA1 and the second green emission area GEA2 of the green sub-pixel G-SP in the corresponding pixel area PA, and the first blue emission area BEA1 and the second blue emission area BEA2 of the blue sub-pixel B-SP in each pixel area PA can be disposed outside the green sub-pixel G-SP. The other configurations are substantially the same so that a redundant description will be omitted. Thus, in the display apparatus according to the embodiment of the present disclosure, the malfunction of the red sub-pixel R-SP, the blue sub-pixel B-SP and the green sub-pixel G-SP in each pixel area PA due to the current leaked from adjacent pixel area PA can be effectively prevented. However, the present disclosure is not limited to the above described embodiments. The position of the green sub-pixel and the position of the blue or sub-pixel can be exchangeable too. By separating two adjacent sub-pixels with a light-emitting device of another sub-pixel of each pixel area PA, the malfunction of the two adjacent sub-pixels due to the leakage current can be prevented. Furthermore, depending on the materials of light-emitting devices of different sub-pixels, any one the blue sub-pixel B-SP, the red sub-pixel R-SP and the green sub-pixel G-SP may have a light-emitting device with a driving voltage higher than those of the remaining two sub-pixels. Thus, by separating two adjacent sub-pixels with a light-emitting device having a higher driving voltage of another sub-pixel of each pixel area PA, the malfunction of the other sub-pixel due to the leakage current can be prevented. Therefore, in the above and following description, the blue sub-pixel may be referred to as one of a first sub-pixel, a second sub-pixel and a third sub-pixel, the red sub-pixel may be referred to as another of the first sub-pixel, the second sub-pixel and the third sub-pixel, and the green sub-pixel may be referred to as the remaining one of the first sub-pixel, the second sub-pixel and the third sub-pixel.

As shown in FIGS. 5 and 6, an encapsulation structure 400 can be disposed on the plurality of light-emitting devices (301 and 302) of each sub-pixel (R-SP, B-SP and G-SP). The encapsulation structure 400 can prevent the damage of the plurality of light-emitting devices (301 and 302) in each sub-pixel (R-SP, B-SP and G-SP) due to external impact and moisture. The encapsulation structure 400 can have a multi-layer structure. For example, the encapsulation structure 400 can include a first encapsulating layer 410, a second encapsulating layer 420 and a third encapsulating layer 430, which are sequentially stacked. The first encapsulating layer 410, the second encapsulating layer 420 and the third encapsulating layer 430 can include an insulating material. The second encapsulating layer 420 can include a material having a higher fluidity than the first encapsulating layer 410 and the third encapsulating layer 430. For example, the first encapsulating layer 410 and the third encapsulating layer 430 can be an inorganic insulating layer made of an inorganic insulating material, and the second encapsulating layer 420 can be an organic insulating layer made of an organic insulating material. A thickness difference due to the plurality of light-emitting devices (301 and 302) of each sub-pixel (R-SP, B-SP and G-SP) can be removed by the second encapsulating layer 420. For example, an upper surface of the encapsulation structure 400 opposite to the device substrate 100 can be flat.

A barrier structure 500 can be disposed on the encapsulation structure 400. The barrier structure 500 can limit the travelling direction of the light emitted from each light-emitting device (301 and 302). The barrier structure 500 can have a multi-layer structure. For example, the barrier structure 500 can have a stacked structure of a first barrier pattern 510 and a second barrier pattern 520.

The first barrier pattern 510 can be disposed close to the encapsulation structure 400. For example, a lower surface of the first barrier pattern 510 toward the device substrate 100 can be in direct contact with the upper surface of the encapsulation structure 400. The first barrier pattern 510 can include a material capable of blocking light. For example, the first barrier pattern 510 can include a black dye, such as carbon black. The first barrier pattern 510 can be disposed outside the first emission area (REA1, BEA1 and GEA1) and the second emission area (REA2, BEA2 and GEA2) defined in each sub-pixel (R-SP, B-SP and G-SP). For example, the first barrier pattern 510 can overlap the bank insulating layer 150. An area of the device substrate 100 overlapping with the bank insulating layer 150 can be defined as a non-emission area. For example, the first barrier pattern 510 can be disposed within the non-emission area.

The second barrier pattern 520 can be disposed on the first barrier pattern 510. The second barrier pattern 520 can be spaced apart from the first barrier pattern 510. For example, an optical insulating layer 600 covering the first barrier pattern 510 can be disposed on the encapsulation structure 400, and the second barrier pattern 520 can be disposed on the optical insulating layer 600. The optical insulating layer 600 can include an insulating material. The optical insulating layer 600 can include a transparent material. For example, the optical insulating layer 600 can include an organic insulating material. The optical insulating layer 600 can overlap the first emission area (REA1, BEA1 and GEA1) and the second emission area (REA2, BEA2 and GEA2) of each sub-pixel (R-SP, B-SP and G-SP). Thus, in the display apparatus according to the embodiment of the present disclosure, an optical distance of the light emitted from the first light-emitting device 301 of each sub-pixel (R-SP, B-SP and G-SP) and an optical distance of the light emitted from the second light-emitting device 302 of each sub-pixel (R-SP, B-SP and G-SP) can be sufficiently secured. The optical distance refers to a distance between a light-emitting device and a lens disposed on the light-emitting device.

The second barrier pattern 520 can include a material capable of blocking light. For example, the second barrier pattern 520 can include a black dye, such as carbon black. The second barrier pattern 520 can include a same material as the first barrier pattern 510. The second barrier pattern 520 can be disposed outside the first emission area (REA1, BEA1 and GEA1) and the second emission area (REA2, BEA2 and GEA2) defined in each sub-pixel (R-SP, B-SP and G-SP). Thus, in the display apparatus according to the embodiment of the present disclosure, the unintended color mixing can be prevented.

Pixel lenses 700 can be disposed on the optical insulating layer 600. The pixel lenses 700 can overlap the emission areas (REA1, REA2, BEA1, BEA2, GEA1 and GEA2) of each sub-pixel (R-SP, B-SP and G-SP). For example, the pixel lenses 700 can include first pixel lenses 710 overlapping with the first emission area (REA1, BEA1 and GEA1) of each sub-pixel (R-SP, B-SP and G-SP) and second pixel lenses 720 overlapping with the second emission area (REA2, BEA2 and GEA2) of each sub-pixel (R-SP, B-SP and G-SP). The light emitted from the first light-emitting device 301 of each sub-pixel (R-SP, B-SP and G-SP) can be focused by one of the first pixel lenses 710, and the light emitted from the second light-emitting device 302 of each sub-pixel (R-SP, B-SP and G-SP) can be focused by one of the second pixel lenses 720. For example, the first pixel lenses 710 and the second pixel lenses 720 can function as a convex lens. A surface of each first pixel lens 710 and a surface of each second pixel lens 720 which are opposite to the optical insulating layer 600 can have a convex shape. Thus, in the display apparatus according to the embodiment of the present disclosure, the light extraction efficiency of each sub-pixel (R-SP, B-SP and G-SP) can be improved.

As shown in FIGS. 2 and 3, the first pixel lens 710 on each sub-pixel (R-SP, B-SP and G-SP) can have a planar shape corresponding to the first emission area (REA1, BEA1 and GEA1) of the corresponding sub-pixel (R-SP, B-SP and G-SP). For example, a plane of first pixel lens 710 on each sub-pixel (R-SP, B-SP and G-SP) can have a shape of a bar extending in the first direction X. The second pixel lens 720 on each sub-pixel (R-SP, B-SP and G-SP) can have a planar shape corresponding to the second emission area (REA2, BEA2 and GEA2) of the corresponding sub-pixel (R-SP, B-SP and G-SP). For example, a plane of the second pixel lens 720 on each sub-pixel (R-SP, B-SP and G-SP) can have a circular shape. The second pixel lenses 720 can include a same material as the first pixel lenses 710. The second pixel lenses 720 can be disposed on a same layer as the first pixel lenses 710. The second pixel lenses 720 can be formed by a same process as the first pixel lenses 710. For example, the second pixel lenses 720 can be formed simultaneously with the first pixel lenses 710. Thus, in the display apparatus according to the embodiment of the present disclosure, a process of forming the pixel lenses 700 can be simplified.

As shown in FIGS. 5 and 6, a lens passivation layer 800 can be disposed on the first pixel lenses 710 and the second pixel lenses 720. The lens passivation layer 800 can prevent the damage of the first pixel lenses 710 and the damage of the second pixel lenses 720 due to the external impact. For example, the first pixel lenses 710 and the second pixel lenses 720 can be completely covered by the lens passivation layer 800. The lens passivation layer 800 can include an insulating material. The lens passivation layer 800 can include a transparent material. For example, the lens passivation layer 800 can include an organic insulating material. An upper surface of the lens passivation layer 800 opposite to the device substrate 100 can be flat.

A refractive index of the lens passivation layer 800 can be smaller than a refractive index of each first pixel lens 710 and a refractive index of each second pixel lens 720. Thus, in the display apparatus according to the embodiment of the present disclosure, the light passing through each first pixel lens 710 can't be reflected toward the device substrate 100 at a boundary between the corresponding first pixel lens 710 and the lens passivation layer 800. And, in the display apparatus according to the embodiment of the present disclosure, the light passing through each second pixel lens 720 can't be reflected toward the device substrate 100 at a boundary between the corresponding second pixel lens 720 and the lens passivation layer 800. Therefore, in the display apparatus according to the embodiment of the present disclosure, the light extraction efficiency can be effectively improved.

Accordingly, the display apparatus according to the embodiment of the present disclosure can include the red sub-pixel R-SP, the blue sub-pixel B-SP and the green sub-pixel G-SP in each pixel area PA, wherein each of the sub-pixel (R-SP, B-SP and G-SP) can include the first emission area (REA1, BEA1 and GEA1) having a planar shape of a bar extending in the first direction X and the second emission area (REA2, BEA2 and GEA2) having a planar shape different from the first emission area (REA1, BEA1 and GEA1), wherein the second emission area (REA2, BEA2 and GEA2) of each sub-pixel (R-SP, B-SP and G-SP) can be disposed side by side with the first emission area (REA1, BEA1 and GEA1) of the corresponding sub-pixel (R-SP, B-SP and G-SP) in the second direction Y perpendicular to the first direction X, and wherein the first blue emission area BEA1 and the second blue emission area BEA2 of the blue sub-pixel B-SP which are disposed in a same order as the first red emission area REA1 and the second red emission area REA2 of the red sub-pixel R-SP can be disposed between the first green emission area GEA1 and the second green emission area GEA2 of the green sub-pixel G-SP. Thus, in the display apparatus according to the embodiment of the present disclosure, the malfunction of the sub-pixels (R-SP, B-SP and G-SP) in each pixel area PA due to the leakage current can be prevented. Therefore, in the display apparatus according to the embodiment of the present disclosure, the decrease in the quality of the image due to the malfunction of the sub-pixels (R-SP, B-SP and G-SP) can be minimized.

The display apparatus according to the embodiment of the present disclosure is described that the driving circuit DC of each sub-pixel (R-SP, B-SP and G-SP) consists of the first thin film transistor TR1, the second thin film transistor TR2, the first control thin film transistor TC1, the second control thin film transistor TC2 and the storage capacitor Cst. However, in the display apparatus according to another embodiment of the present disclosure, the driving circuit DC of each sub-pixel (R-SP, B-SP and G-SP) can include various switching thin film transistors. For example, in the display apparatus according to another embodiment of the present disclosure, the driving circuit DC of each sub-pixel (R-SP, B-SP and G-SP) can further include a third thin film transistor to initialize the storage capacitor Cst of the corresponding sub-pixel (R-SP, B-SP and G-SP) according to the gate signal. Thus, in the display apparatus according to another embodiment of the present disclosure, the degree of freedom in the configuration of the driving circuit DC in each sub-pixel (R-SP, B-SP and G-SP) can be improved.

In the display apparatus according to another embodiment of the present disclosure, the location and the electric connection of the first drain electrode, the first source electrode, the second drain electrodes 225 and the second source electrode 227 in each driving circuit DC can vary depending on the configuration of the corresponding driving circuit DC and/or the type of the corresponding thin film transistors (TR1 and TR2). For example, in the display apparatus according to another embodiment of the present disclosure, the second gate electrode 223 of each driving circuit DC can be electrically connected to the first drain electrode of the corresponding driving circuit DC. Thus, in the display apparatus according to another embodiment of the present disclosure, the degree of freedom in the configuration of each driving circuit DC and the type of each thin film transistor (TR1 and TR2) can be improved.

The display apparatus according to the embodiment of the present disclosure is described that each of the first pixel lenses 710 is disposed on the first emission areas (REA1, BEA1 and GEA1) of one of the sub-pixels (R-SP, B-SP and G-SP), and each of the second pixel lenses 720 is disposed on the second emission area (REA2, BEA2 and GEA2) of one of the sub-pixels (R-SP, B-SP and G-SP). However, in the display apparatus according to another embodiment of the present disclosure, the first pixel lenses 710 and/or the second pixel lenses 720 can be omitted. For example, in the display apparatus according to another embodiment of the present disclosure, the lens passivation layer 800 can be in direct contact with the upper surface of the optical insulating layer 600 overlapping with the first emission area (REA1, BEA1 and GEA1) of each sub-pixel (R-SP, B-SP and G-SP). Thus, in the display apparatus according to another embodiment of the present disclosure, the image realized by the second emission area (REA2, BEA2 and GEA2) of each sub-pixel (R-SP, B-SP and G-SP) can have a narrow viewing angle by the second pixel lenses 720, and a viewing angle of the image realized by the first emission area (REA1, BEA1 and GEA1) of each sub-pixel (R-SP, B-SP and G-SP) can be significantly increased by omitting the first pixel lenses 710.

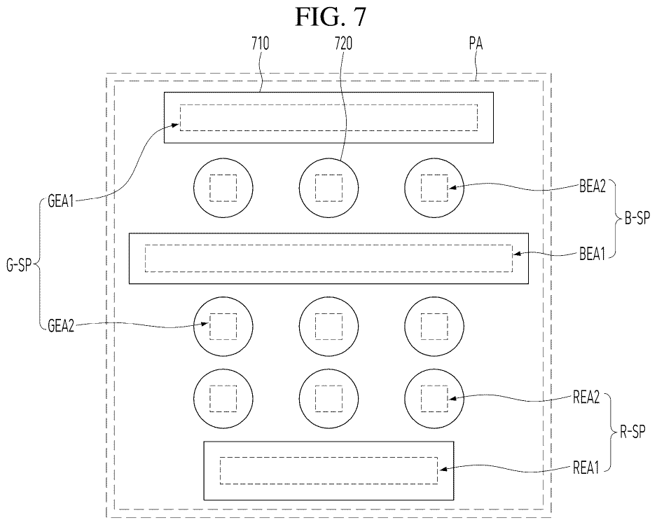

The display apparatus according to the embodiment of the present disclosure is described that a single first emission area (REA1, BEA1 and GEA1) and two second emission areas (REA2, BEA2 and GEA2) are defined in each sub-pixel (R-SP, B-SP and G-SP). However, in the display apparatus according to another embodiment of the present disclosure, a single second emission area (REA2, BEA2 and GEA2) or a plurality of second emission areas (REA2, BEA2 and GEA2) can be defined in each sub-pixel (R-SP, B-SP and G-SP). For example, in the display apparatus according to another embodiment of the present disclosure, three second emission areas (REA2, BEA2 and GEA2) can be defined in each sub-pixel (R-SP, B-SP and G-SP), as shown in FIG. 7. Thus, in the display apparatus according to another embodiment of the present disclosure, the degree of freedom in the configuration of each sub-pixel (R-SP, B-SP and G-SP) can be improved.

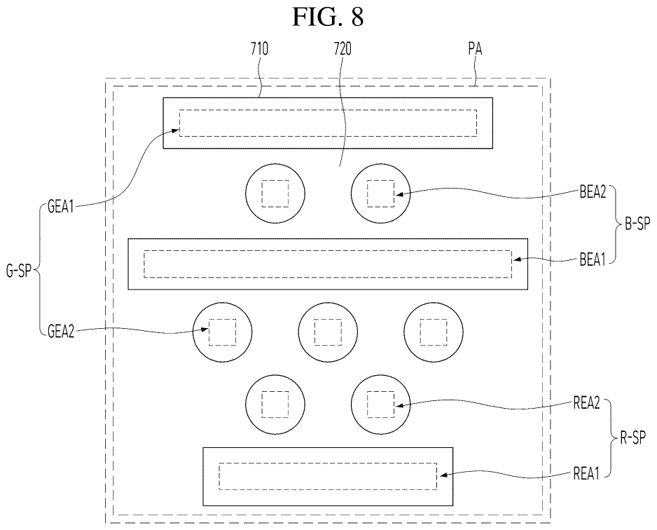

In the display apparatus according to the embodiment of the present disclosure, a number of second emission areas (REA2, BEA2 and GEA2) of each of the sub-pixels (R-SP, B-SP and G-SP) is the same in each pixel area PA. However, in the display apparatus according to another embodiment of the present disclosure, at least one of the sub-pixels (R-SP, B-SP and G-SP) in each pixel area PA can include a number of second emission areas (REA2, BEA2 and GEA2) different from a number of second emission areas included in the other sub-pixels (R-SP, B-SP and G-SP) in the corresponding pixel area PA. For example, in the display apparatus according to another embodiment of the present disclosure, the red sub-pixel R-SP and the blue sub-pixel B-SP of each pixel area PA can include two second emission areas (REA2 and BEA2), and the green sub-pixel G-SP of each pixel area PA can include three second emission areas (GEA2), as shown in FIG. 8. Thus, in the display apparatus according to another embodiment of the present disclosure, the leakage current can be effectively blocked between the red sub-pixel R-SP and the blue sub-pixel B-SP of each pixel area PA. Therefore, in the display apparatus according to another embodiment of the present disclosure, the malfunction of the first light-emitting device 301 and the second light-emitting device 302 of each sub-pixel (R-SP, B-SP and G-SP) due to the leakage current can be effectively prevented.

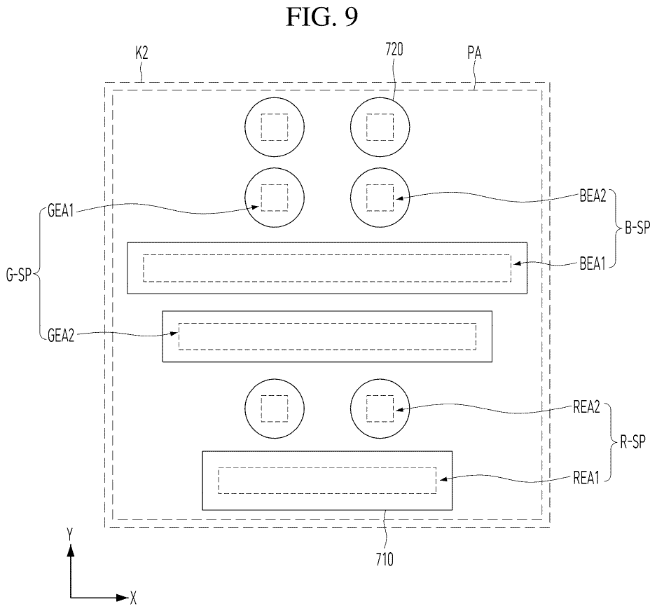

The display apparatus according to the embodiment of the present disclosure is described that the second green emission area GEA2 of the green sub-pixel G-SP in each pixel area PA is disposed between the red sub-pixel R-SP and the blue sub-pixel B-SP of the corresponding pixel area PA. However, in the display apparatus according to another embodiment of the present disclosure, the first green emission area GEA1 of the green sub-pixel G-SP in each pixel area PA can be disposed between the red sub-pixel R-SP and the blue sub-pixel B-SP of the corresponding pixel area PA, as shown in FIG. 9. Thus, in the display apparatus according to another embodiment of the present disclosure, the leakage current between the red sub-pixel R-SP and the blue sub-pixel B-SP of each pixel area PA can be blocked by the first green emission area GEA1 of the green sub-pixel G-SP in the corresponding pixel area PA. Therefore, in the display apparatus according to another embodiment of the present disclosure, the malfunction of the first light-emitting device 301 and the second light-emitting device 302 of each sub-pixel (R-SP, B-SP and G-SP) due to the leakage current can be effectively prevented.

The first light-emitting device 301 of the green sub-pixel G-SP in each pixel area PA can have a driving voltage higher than the first light-emitting device 301 of the blue sub-pixel B-SP in the corresponding pixel area PA. For example, in the display apparatus according to the embodiment of the present disclosure, the first light-emitting device 301 of the green sub-pixel G-SP in each pixel area PA can't be operated by the current leaked from the first red emission area REA1 of the red sub-pixel R-SP in the corresponding pixel area PA. The first light-emitting device 301 of the green sub-pixel G-SP in each pixel area PA can have a driving voltage higher than the first light-emitting device 301 of the red sub-pixel R-SP in the corresponding pixel area PA. For example, in the display apparatus according to the embodiment of the present disclosure, the first light-emitting device 301 of the green sub-pixel G-SP in each pixel area PA can't be operated by the current leaked from the first blue emission area BEA2 of the blue sub-pixel B-SP in the corresponding pixel area PA. Therefore, in the display apparatus according to the embodiment of the present disclosure, the malfunction of the first green emission area GEA1 of the green sub-pixel G-SP in each pixel area PA due to the leakage current can be prevented. However, the present disclosure is not limited thereto. As described above, any one the blue sub-pixel B-SP, the red sub-pixel R-SP and the green sub-pixel G-SP may have a light-emitting device with a driving voltage higher than those of the remaining two sub-pixels depending on the materials of different light-emitting devices.

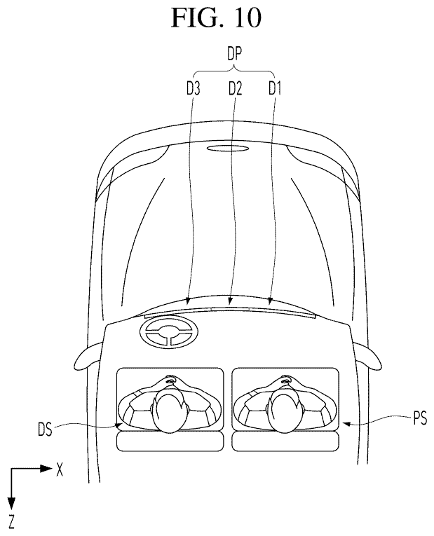

The display apparatus according to the embodiment of the present disclosure is described that the display panel DP is installed in front of the passenger seat PS. However, in the display apparatus according to another embodiment of the present disclosure, the display panel DP can be installed on various locations. For example, in the display apparatus according to another embodiment of the present disclosure, the display panel DP can include a first display area D1 disposed in front of the passenger seat PS, a second display area D2 disposed between the driver seat DS and the passenger seat PS, and a third display area D3 disposed in front of the driver seat DS, as shown in FIG. 10.

The second display area D2 and the third display area D3 can have a same structure as the first display area D1. For example, an image realized by the first display area D1 (particularly, by the second light-emitting devices of each sub-pixel) can't be recognized by the driver sitting in the driver seat DS. For example, an image realized by the third display area D3 (particularly, by the second light-emitting devices of each sub-pixel) can't be recognized by the passenger sitting in the passenger seat PS. The first display area D1, the second display area D2 and the third display area D3 can be physically combined. For example, a boundary between the first display area D1 and the second display area D2 and a boundary between the second display area D2 and the third display area D3 can't be recognized. Thus, in the display apparatus according to another embodiment of the present disclosure, the degree of freedom in the configuration of the display panel DP can be improved.

In the result, the display apparatus according to the embodiments of the present disclosure can comprise a plurality of pixel areas, wherein a first sub-pixel, a second sub-pixel and a third sub-pixel can be disposed in each pixel area, the second sub-pixel realizing a different color from the first sub-pixel and the third sub-pixel realizing a different color from the first sub-pixel and the second sub-pixel, wherein each sub-pixel can include a first emission area having a planar shape of a bar extending in a first direction and a second emission area having a planar shape different from the first emission area, wherein the second emission area of each sub-pixel can be disposed side by side with the first emission area of the corresponding sub-pixel in a second direction perpendicular to the first direction, and wherein the first emission area and the second emission area of the first sub-pixel which are disposed in a same order as the first emission area and the second emission area of the second sub-pixel can be disposed between the first emission area and the second emission area of the third sub-pixel and the first emission area and the second emission area of the second sub-pixel can be disposed outside the first emission area and the second emission area of the third sub-pixel. Thus, in the display apparatus according to the embodiments of the present disclosure, the malfunction of the first sub-pixel, the second sub-pixel and the third sub-pixel in each pixel area due to the leakage current can be prevented. Thereby, in the display apparatus according to the embodiments of the present disclosure, the decrease in the quality of the (particularly, low-grayscale) image due to the malfunction of the first sub-pixel, the second sub-pixel and the third sub-pixel in each pixel area can be minimized. And, in the display apparatus according to the embodiments of the present disclosure, the low power operation can be possible, and the power consumption can be reduced.

What is claimed is:

1. A display apparatus comprising:
a plurality of pixel areas, wherein a first sub-pixel, a second sub-pixel and a third sub-pixel are disposed in each pixel area, the second sub-pixel realizing a different color from the first sub-pixel and the third sub-pixel realizing a different color from the first sub-pixel and the second sub-pixel,
wherein each of the first sub-pixel, the second sub-pixel and the third sub-pixel includes a first emission area having a planar shape of a bar extending in a first direction and a second emission area having a planar shape different from the first emission area,
wherein the second emission area of each of the first sub-pixel, the second sub-pixel and the third sub-pixel is disposed side by side with the first emission area of the corresponding sub-pixel in a second direction perpendicular to the first direction, and
wherein the first emission area and the second emission area of the first sub-pixel which are disposed in a same order as the first emission area and the second emission area of the second sub-pixel are disposed between the first emission area and the second emission area of the third sub-pixel, and the first emission area and the second emission area of the second sub-pixel are disposed outside the first emission area and the second emission area of the third sub-pixel.

2. The display apparatus according to claim 1, wherein the second emission area of the third sub-pixel is disposed between the first emission area of the first sub-pixel and the second emission area of the second sub-pixel, or the first emission area of the third sub-pixel is disposed between the first emission area of the first sub-pixel and the second emission area of the second sub-pixel.

3. The display apparatus according to claim 1, wherein each of the first sub-pixel, the second sub-pixel and the third sub-pixel includes a plurality of second emission areas, and
wherein the plurality of second emission areas is disposed side by side in the first direction.

4. The display apparatus according to claim 3, wherein at least one of the first sub-pixel, the second sub-pixel and the third sub-pixel has a number of second emission areas different from respective numbers of second emission areas of the other sub-pixels.

5. The display apparatus according to claim 1, further comprising a plurality of light-emitting devices disposed in the first emission area and the second emission area of each of the first sub-pixel, the second sub-pixel and the third sub-pixel,
wherein the plurality of light-emitting devices of the third sub-pixel have a driving voltage higher than the plurality of light-emitting devices of the first sub-pixel and the plurality of light-emitting devices of the second sub-pixel.

6. The display apparatus according to claim 5, wherein the plurality of light-emitting devices include first light-emitting devices overlapping with the first emission area of each of the first sub-pixel, the second sub-pixel and the third sub-pixel and second light-emitting devices overlapping with the second emission area of each of the first sub-pixel, the second sub-pixel and the third sub-pixel, and
wherein each second light-emitting device has a stacked structure same as each first light-emitting device.

7. The display apparatus according to claim 5, wherein the first emission area and the second emission area of the third sub-pixel emit green light.

8. The display apparatus according to claim 1, wherein a distance between the first emission area of the first sub-pixel and the first emission area of the second sub-pixel of each pixel area is smaller than a distance between the first emission area of the second sub-pixel of each pixel area and the first emission area of the first sub-pixel of the pixel area adjacent to the corresponding pixel area in the second direction, and
wherein a distance between the second emission area of the first sub-pixel and the second emission area of the second sub-pixel of each pixel area is smaller than a distance between the second emission area of the second sub-pixel of each pixel area and the second emission area of the first sub-pixel of the pixel area adjacent to the corresponding pixel area in the second direction.

9. The display apparatus according to claim 8, wherein the distance between the first emission area of the first sub-pixel and the first emission area of the second sub-pixel of each pixel area is the same as the distance between the second emission area of the first sub-pixel and the second emission area of the second sub-pixel of the corresponding pixel area in the second direction.

10. The display apparatus according to claim 1, wherein the first emission areas of the first sub-pixel, the second sub-pixel and the third sub-pixel have different lengths in the first direction.

11. The display apparatus according to claim 10, wherein the first emission area of the third sub-pixel has a smaller length than the first emission area of the first sub-pixel in the first direction, and the first emission area of the second sub-pixel has a smaller length than the first emission area of the third sub-pixel in the first direction.

12. The display apparatus according to claim 1, wherein the second emission areas of the first sub-pixel, the second sub-pixel and the third sub-pixel have the same length in the second direction and the second emission area of each sub-pixel has a smaller length than the first emission areas of the corresponding sub-pixel in the first direction.

13. The display apparatus according to claim 1, wherein light emitted from the first emission area of each sub-pixel has a viewing angle wider than light emitted from the second emission area of each sub-pixel; or wherein the first emission area of each sub-pixel is configured to realize a first image and the second emission area of each sub-pixel is configured to realize a second image different from the first image.

14. The display apparatus according to claim 1, wherein a first pixel lens is disposed to overlap the first emission area of each sub-pixel and a second pixel lens is disposed to overlap the second emission area of each sub-pixel, and wherein a lens passivation layer is disposed on the first pixel lens and the second pixel lens.

15. The display apparatus according to claim 14, wherein a refractive index of the lens passivation layer is smaller than a refractive index of the first pixel lens and a refractive index of the second pixel lens.

16. The display apparatus according to claim 1, wherein a barrier structure is disposed outside the first emission area and the second emission area defined in each sub-pixel.

17. The display apparatus according to claim 16, wherein the barrier structure has a stacked structure of a first barrier pattern and a second barrier pattern disposed on the first barrier pattern.

18. The display apparatus according to claim 17, wherein the second barrier pattern is spaced apart from the first barrier pattern by an optical insulating layer covering the first barrier pattern.

19. The display apparatus according to claim 18, wherein a pixel lens is disposed in the second emission area of each sub-pixel, and a lens passivation layer is disposed on the pixel lens and is in direct contact with the optical insulating layer in the first emission area.

20. The display apparatus according to claim 1, wherein the first sub-pixel is one of a blue sub-pixel, a red sub-pixel and a green sub-pixel, the second sub-pixel is another of the blue sub-pixel, the red sub-pixel, and the green sub-pixel, and the third sub-pixel is the remaining one of the blue sub-pixel, the red sub-pixel and the green sub-pixel.
